(19) United States
(12) Patent Application Publication
(10) Pub. No.: US 2021/0277500 A1
(43) Pub. Date: Sep. 9, 2021

(54) METHOD FOR PREPARING SINGLE CRYSTAL SUPERALLOY TEST BARS BY USING NI-W HETEROGENEOUS SEED CRYSTAL

(71) Applicant: Northwestern Polytechnical University, Xi'an (CN)

(72) Inventors: Wenchao YANG, Xi'an (CN); Jiarun QIN, Xi'an (CN); Pengfei QU, Xi'an (CN); Lin LIU, Xi'an (CN); Jun ZHANG, Xi'an (CN); Haijun SU, Xi'an (CN); Taiwen HUANG, Xi'an (CN); Min GUO, Xi'an (CN); Yueling GUO, Xi'an (CN)

(73) Assignee: Northwestern Polytechnical University, Xi'an (CN)

(21) Appl. No.: 17/126,359

(22) Filed: Dec. 18, 2020

(30) Foreign Application Priority Data
Feb. 4, 2020 (CN) 202010079827.1

(51) Int. Cl. C22C 1/03; C22C 19/03; C30B 15/36; C30B 15/10; C30B 15/24; C30B 15/16

(52) U.S. Cl. CPC C22C 1/03; C22C 19/03; C30B 15/16; C30B 15/10; C30B 15/24; C30B 15/36

(57) ABSTRACT

In the method for preparing single crystal superalloy test bars by using a Ni—W heterogeneous seed crystal, on the premise of ensuring that the single crystal superalloy has the required orientation, by reusing the seed crystal, it is achieved that the trouble caused by the need of preparing a new seed crystal when a single crystal superalloy is produced by the seed crystal method every time is avoided, and the production cost is significantly reduced. In the present disclosure, the formation of the stray grains in mushy zone could be avoided by using a Ni—W heterogeneous seed crystal without mushy zone and a built-in corundum tube.

### CROSS REFERENCE TO RELATED APPLICATION

This application claims the priority of Chinese Patent Application No. 202010079827.1, entitled “Method for preparing DD3 single crystal superalloy test bars by using Ni—W heterogeneous seed crystal” filed with the China National Intellectual Property Administration on Feb. 4, 2020, which is incorporated herein by reference in its entirety.

### TECHNICAL FIELD

The present disclosure relates to the field of the preparation of single crystal superalloys, and in particular to a method for preparing single crystal superalloys, in which the formation of mushy zones of the seed crystal can be eliminated by using a Ni—W heterogeneous seed crystal, and at the same time, the reuse of the original high seed crystal can be realized by a built-in corundum tube.

### BACKGROUND

With the increase of the temperature in the front inlet of aeroengine turbines, the technology for preparing single crystal turbine blades has made great progress. In most turbine blades, the [001] orientation has been used as the radial direction of the blades, this is because the high temperature creep performance is the best when the [001] orientation of the single crystal superalloy is consistent with the maximum stress direction of the blades. The current methods for preparing a single crystal include a grain selection method and a seed crystal method. The grain selection method is simple for the preparation of single crystals due to no need of preparing seed crystals, but the angle between the crystal orientation and the longitudinal direction of a casting could only be controlled within 15° by this method. The seed crystal method is to produce a casting with the same orientation as the seed crystal by remelting the seed crystal and stacking atoms on the same.

The mechanisms for the formation of stray grains in the mushy zone of seed crystals mainly includes: the first one is that during the alloy casting, the casting alloy scours part of the melted seed crystals, and then they enter into the gap between the unmelted seed crystals and the shell mould, which results in a large supercooling, leading to form stray grains at the edge of the seed crystals below the melt-back interface; the second one is that the casting alloy scours the mushy zone below the melt-back interface, resulting in a deformation of the unmelted seed crystal in the mushy zone, which is the origin of small-angle grain boundary or stray grains; the third one is that when the directional solidification is started, the isothermal surface of the seed crystal segment will rapidly change from convex interface to concave interface at the holding stage, so that a great supercooling would be generated within the solidification distance of 1-2 mm above the melt-back interface, leading to form stray grains at the edge of the seed crystals.

The formation mechanism of stray grains in the mushy zone has been studied by N. Stanford, A. Djakovic et al. in “Defect grains in the melt-back region of cmxs-4 single crystal seeds” published in Superalloys 2004. CN 1570224A and CN 101255604A propose to prepare single crystal superalloys by presetting seed crystals in a shell mould. CN 105839186A proposes a method for preparing single crystal superalloys in which the seed crystal could be cut in sequence to avoid the mushy zone, and the shell mould that has a corundum pipe pre-embedded therein is adopted. With the above methods, the formation of stray grains can be partly reduced, while the formation of the mushy zone can not be eliminated, resulting in that the seed crystal cannot be reused in its original length during the production. Using the seed crystal method to prepare single crystal superalloys in the prior art has the shortcoming that the production cost is very high due to the need of new seed crystals after the preparation is preformed for several times.

### SUMMARY

In order to overcome the defects in the prior art that the stray grains are easy to grow in the mushy zone of seed crystals, the single crystal may fail to orient and the seed crystal cannot be reused when preparing single crystals, the present disclosure provides a method for preparing single crystal superalloy test bars by using a Ni—W heterogeneous seed crystal.

The method according to the present disclosure specifically comprises:

Step 1: preparing a shell mould

The shell mould comprises a casting segment and a seed crystal segment with a corundum tube. The seed crystal segment has a length equal to that of the corundum tube, and before preparing a seed crystal, the corundum tube is put into the seed crystal segment. The corundum tube has an inner diameter of 6.98-11.98 mm and a length of 40 mm.

Step 2: preparing a seed crystal for preparing Ni—W heterogeneous single crystal test bars

A single crystal test bar is prepared by a grain selection method.

In the preparation of a seed crystal for preparing the Ni—W heterogeneous single crystal test bar, a single crystal cylinder with a [001] orientation which deviates from the axial direction by 0-12° is directionally cut from the single crystal test bar and used as a seed crystal. The directionally cut seed crystal is cylindrical in shape and has a [001] orientation which deviates from the axial direction by 0-12°; the seed crystal has a diameter of 6.93-11.94 mm and a length of 25 mm. The seed crystal is sanded down to be smooth with a 1200 # sandpaper.

A single crystal cylinder with a [001] orientation which deviates from the axial direction by 0° is directionally cut from the single crystal test bar with a wire-cut electric discharge machine and used as a seed crystal. The directionally cut seed crystal is cylindrical in shape and has a [001] orientation which deviates from the axial direction by 0°; the seed crystal has a diameter of 6.93 mm and a length of 25 mm. The seed crystal is sanded down to be smooth with a 1200 # sandpaper.

Step 3: preparing a first Ni—W heterogeneous single crystal test bar with a [001] orientation which deviates from the axial direction by 0-12°

A Ni—W heterogeneous single test bar with a [001] orientation which deviates from the axial direction by 0-12° is prepared by using the seed crystal obtained in step 2. The specific process comprises:

Another corundum tube is taken as a container for preparing a Ni—W heterogeneous single crystal test bar, wherein the corundum tube has an inner diameter of 6.97-11.98 mm and a length of 115 mm.

A Ni—W alloy is used as a master alloy, and the obtained seed crystal and the Ni—W master alloy are put into the corundum tube in the order of the former at the bottom and the latter on the top; the corundum tube filled with the seed crystal and the master alloy is installed on the bottom platform of a LMC directional solidification furnace.

The directional solidification furnace is heated to 1550° C. at a rate of 10° C./min and held for 40-50 min, so as to melt the master alloy in the corundum tube and produce a mushy zone with a length of 2-3 mm on the seed crystal. After the holding is completed, the obtained system is subjected to a crystal pulling by pulling down at a rate of 10 μm/s-100 μm/s. After the crystal pulling is completed, the corundum tube is taken out after the directional solidification furnace is cooled to 100° C., to obtain a first Ni—W heterogeneous single crystal test bar with a [001] orientation which deviates from the axial direction by 0-12°.

The first Ni—W heterogeneous single crystal test bar has a diameter of 6.96-11.94 mm, a length of 35 mm, and a gap of 0.02-0.06 mm with the corundum tube.

Step 4: preparing a first single crystal superalloy test bar

The obtained first Ni—W heterogeneous single crystal test bar is cut to obtain a Ni—W heterogeneous seed crystal that can be put into the shell mould. A single crystal superalloy test bar is prepared by using the obtained Ni—W heterogeneous seed crystal.

The specific process comprises:

The obtained Ni—W heterogeneous seed crystal is put into the corundum tube in the shell mould. The shell mould filled with the Ni—W heterogeneous seed crystal is placed in a directional solidification furnace. A purchased superalloy master alloy block is put into an electromagnetic melting crucible at the upper part of the furnace. The directional solidification furnace is heated to a temperature of 1550° C. at a rate of 10° C./min, so as to melt the upper surface of the Ni—W heterogeneous seed crystal near the heater of the directional solidification furnace.

The power of the electromagnetic melting crucible is increased to 7.5 kW, so as to completely melt the superalloy master alloy block in the crucible to obtain a superalloy liquid. The superalloy liquid is cast into the shell mould, and the shell mould is full filled with the superalloy liquid.

A mushy zone with a length of 2-3 mm is generated on the upper part of the Ni—W heterogeneous seed crystal by the cast superalloy liquid and held for 10 min-30 min. The mushy zone is a solid-liquid two-phase region generated at the joint of the superalloy liquid and the Ni—W heterogeneous seed crystal.

After the holding is completed, the obatined system is subjected to a crystal pulling by pulling down at a rate of 40 μm/s-100 μm/s; after the crystal pulling is completed, the product is taken out after the heating furnace is cooled to 300° C., to obtain the first single crystal superalloy test bar with a [001] orientation which deviates from the axial direction by 0-12°.

Step 5: recovering the seed crystal for reuse

The Ni—W heterogeneous seed crystal is recovered for reuse from the obtained first single crystal superalloy test bar with a [001] orientation which deviates from the axial direction by 0-12°. The specific process comprises:

The shell mould on the obtained first single crystal superalloy test bar with a [001] orientation which deviates from the axial direction by 0-12° is removed. The Ni—W heterogeneous seed crystal is cut from the first single crystal superalloy test bar with a [001] orientation which deviates from the axial direction by 0-12° after removing the shell mould and is recovered for reuse.

The Ni—W heterogeneous seed crystal which is cut from the obtained first single crystal superalloy test bar with a [001] orientation which deviates from the axial direction by 0-12° has a length equal to that of the raw Ni—W heterogeneous seed crystal, and has a diameter of 6.94-11.90 mm, so as to ensure the gap between the recovered seed crystal and the inner wall of the corundum tube fall within a range of 0.04-0.15 mm.

Step 6: preparing other single crystal superalloy test bars Other single crystal superalloy test bars are prepared by using the obtained recovered seed crystal, wherein the other single crystal superalloy test bars have a [001] orientation which deviates from the axial direction by 0-12°. The specific process comprises:

The recovered seed crystal is put into the corundum tube in the shell mould. The shell mould is placed in a directional solidification furnace, and the process in step 4 is repeated to obtain a second superalloy test bar.

The process in step 5 is repeated to re-obtain the recovered seed crystal; the process for preparing the second superalloy test bar is repeated to obtain a third superalloy test bar.

The processes of recovering seed crystal and preparing superalloy test bar are repeated until the required number of superalloy test bars are obtained.

So far, the process for preparing single crystal superalloys by using a Ni—W heterogeneous seed crystal is completed.

In some embodiments, the superalloy master alloy block comprises a DD3 superalloy master alloy block.

In some embodiments, the DD3 superalloy is the first generation superalloy developed by Beijing Institute of Aeronautical Materials.

In the present disclosure, on the premise of ensuring that the single crystal superalloy has the required orientation, by reusing the seed crystal, it is achieved that the trouble caused by the need of preparing a new seed crystal when a single crystal superalloy is produced by the seed crystal method every time is avoided, and the production cost is significantly reduced.

According to the present disclosure, through the research on the formation mechanism of the stray grains in the mushy zone of the seed crystal, it is found that the scour of the mushy zone of the seed crystal by liquid phase is an important factor that affects the formation of the stray grains, which has been neglected for a long time. The formation of stray grains in the mushy zone could be avoided by using a Ni—W heterogeneous seed crystal without mushy zone and a built-in corundum tube. This is because that the mushy zone is a solid-liquid two-phase region, and the solid phase is easily broken by the scouring force in the process of melt scouring and acts as the core of nucleation, leading to the formation of stray grains. Therefore, if the mushy zone can be eliminated, when being scoured by the liquid phase, the solid phase can be well avoided from breaking, thereby avoiding the formation of stray grains.

In the present disclosure, using a shell mould with a corundum tube pre-embedded in its crystal segment could effectively control the gap between the seed crystal and the inner wall of the seed crystal segment, and reduce the formation probability of stray grains caused by quenching resulting from the entrance of the alloy into the gap between the shell mould and the unmelted seed crystal due to casting. Meanwhile, the surface roughness of the corundum tube is lower than that of the shell mould, which is beneficial to increase the critical nucleation supercooling degree required for heterogeneous nucleation and inhibit nucleation in the directional solidification process. The method of pre-embedding a corundum tube in the shell mould is also convenient to recover the seed crystal after shaking off the shell mould. The upper end of the corundum tube is the end where the seed crystal segment is connected with the casting segment.

After preparing a single crystal superalloy, the seed crystal is cut from the seed crystal segment according to the height of the seed crystal before use. Since there is no mushy zone, there is no risk of the formation of fuse dendrite caused by repeatedly melting the mushy zone when the cut seed crystal is reused. Fuse dendrite is one of the nucleation cores of stray grains in the mushy zone.

According to the present disclosure, the single crystal superalloy prepared by using the Ni—W heterogeneous seed crystal is shown in FIG. 4, and the seed crystal structure after the seed crystal is reused to prepare the single crystal superalloy is shown in FIG. 5, which show that no stray grain appears in the mushy zone of the seed crystal. This indicates that using the the present method to prepare the single crystal superalloy can effectively avoid the formation of stray grains in the mushy zone and realize the reuse of the seed crystal to produce single crystal superalloy.

### BRIEF DESCRIPTION OF THE DRAWINGS

FIG. 1 shows the structure of the shell mould used in the “seed crystal” method for preparing a single crystal superalloy in the prior art.

FIG. 2 shows the structure of the shell mould that pre-embedded a corundum tube in the seed crystal segment in the prior art.

FIG. 3 shows the structure of the cross-section of the single crystal superalloy test bar prepared according to the present disclosure.

FIG. 4 shows the structure of the longitudinal section of a mushy zone of the seed crystal after the first use of the seed crystal to prepare a single crystal superalloy according to the present disclosure.

FIG. 5 shows the structure of the longitudinal section of a mushy zone of the seed crystal after the third use of the seed crystal to prepare a single crystal superalloy according to the present disclosure.

FIG. 6 shows the flow chart of the method according to the present disclosure.

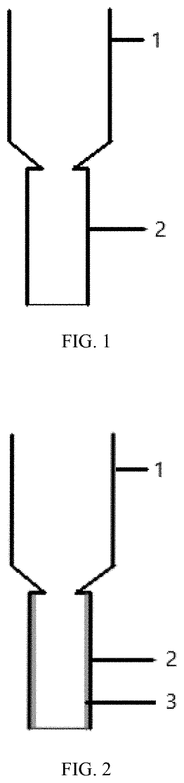

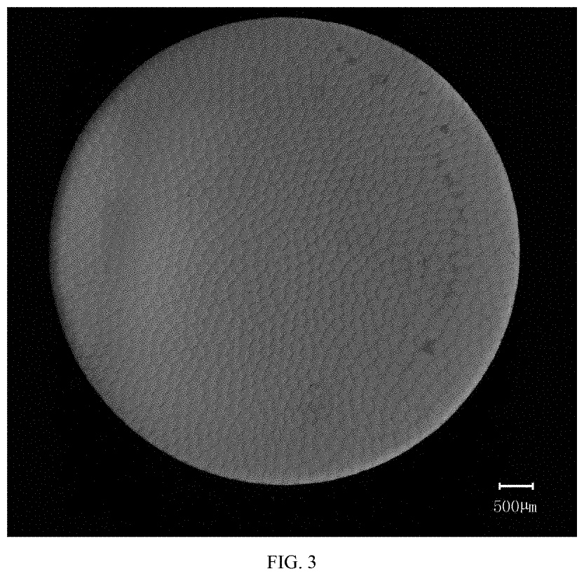

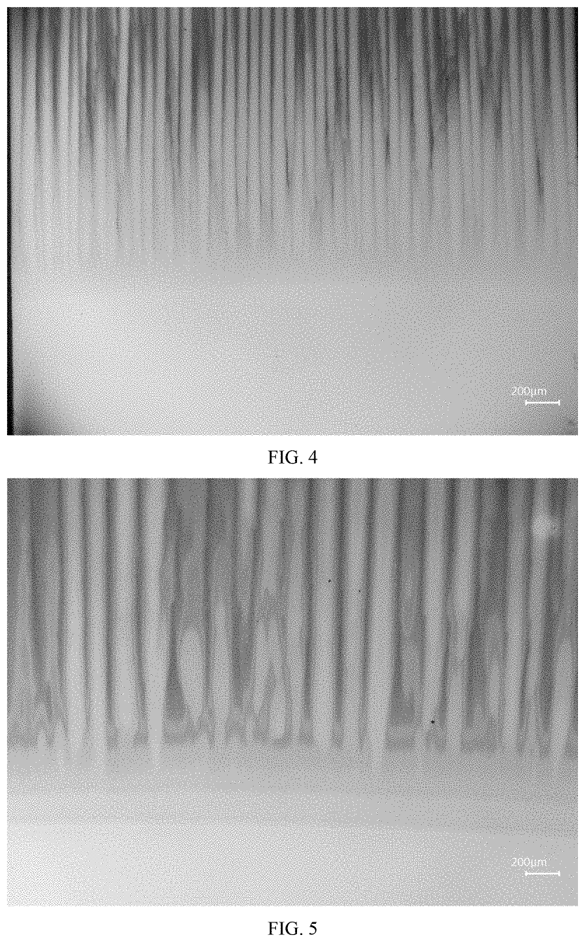

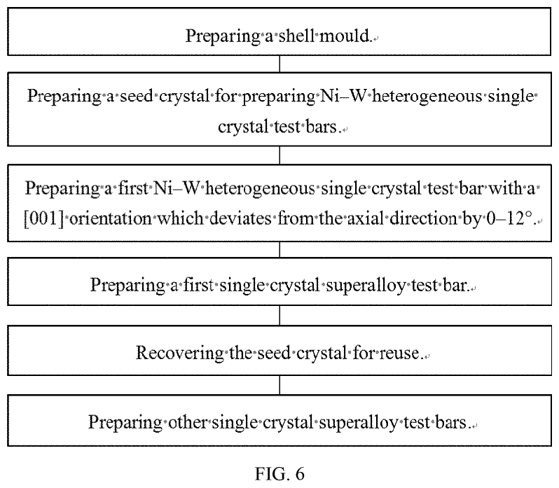

In the drawings: 1 represents a casting segment; 2 represents a seed crystal segment; 3 represents a corundum tube.

### DETAILED DESCRIPTION OF THE EMBODIMENTS

The present disclosure is to provide a method for preparing single crystal superalloy test bars with a [001] orientation which deviates from the axial direction by a angle by reusing a Ni—W heterogeneous seed crystal. With this method, multiple single crystal superalloy test bars is prepared. The [001] orientation of the seed crystal deviates from the axial direction by 0-12°. In each example of the present disclosure, two superalloy test bars were prepared, the [001] orientation of the seed crystal deviates from the axial direction by 0°, and the superalloy master alloy block is a DD3 superalloy master alloy block, wherein the DD3 superalloy is the first generation superalloy developed by Beijing Institute of Aeronautical Materials.

The method according to the present disclosure specifically comprises the following steps:

Step 1: preparing a shell mould.

The shell mould comprises a casting segment 1 and a seed crystal segment 2 with a corundum tube. The seed crystal segment has a length equal to that of the corundum tube, and before preparing a seed crystal, the corundum tube is put into the seed crystal segment 2. The corundum tube has an inner diameter of 6.98-11.98 mm and a length of 40 mm.

The process for preparing a shell mould comprises:

A melted wax material is poured into a mold and solidified to obtain a wax mold base and a cylindrical wax bar respectively, wherein both the wax mold base and the cylindrical wax bar have the same structure as in the prior art.

The corundum tube is full filled with the melted wax material, and the wax material is cooled and solidified to obtain a corundum tube with an inner wax mold. One end of the inner wax mold in the corundum tube is bonded with the plane of the wax mold base, and the other end is connected with the cylindrical wax bar. The joint of the cylindrical wax bar and the inner wax mold in the corundum tube is trimmed to be smooth to obtain a shell-making wax mold.

In the shell-making wax mold, the joint of the inner wax mold in the corundum tube and the wax mold base is a right-angle transition, and the joint of the inner wax mold in the corundum tube and the cylindrical wax bar is a rounded transition.

The shell-making wax mold is subjected to an investment casting by the prior art; that is, the surface of the shell-making wax mold is smeared coating and stuccoed, and then calcined to obtain a shell mould for casting.

The shell mould for casting is washed with water and placed indoors for 24 h to dry it naturally.

Before use, the shell mould for casting is dried in a drying furnace for later use.

Step 2: preparing a seed crystal for preparing Ni—W heterogeneous single crystal test bars:

A single crystal test bar is prepared by a grain selection method.

A single crystal cylinder with a [001] orientation which deviates from the axial direction by 0-12° is directionally cut from the single crystal test bar with a wire-cut electric discharge machine and used as a seed crystal. The directionally cut seed crystal is cylindrical in shape and has a [001] orientation which deviates from the axial direction by 0-12°; the seed crystal has a diameter of 6.93-11.94 mm and a length of 25 mm. The seed crystal is sanded down to be smooth with a 1200 # sandpaper.

A single crystal cylinder with a [001] orientation which deviates from the axial direction by 0° is directionally cut from the single crystal test bar with a wire-cut electric discharge machine and used as a seed crystal. The directionally cut seed crystal is cylindrical in shape and has a [001] orientation which deviates from the axial direction by 0°; the seed crystal has a diameter of 6.93 mm and a length of 25 mm. The seed crystal is sanded down to be smooth with a 1200 # sandpaper.

Step 3: preparing a first Ni—W heterogeneous single crystal test bar with a [001] orientation which deviates from the axial direction by 0-12°:

A Ni—W heterogeneous single test bar with a [001] orientation which deviates from the axial direction by 0-12° is prepared by using the seed crystal obtained in step 2. The specific process comprises:

Another corundum tube is taken as a container for preparing Ni—W heterogeneous single crystal test bars, wherein the corundum tube has an inner diameter of 6.97-11.98 mm and a length of 115 mm.

A Ni—W alloy is used as a master alloy, the obtained seed crystal and the Ni—W master alloy are put into the corundum tube in the order of the former at the bottom and the latter on the top. The corundum tube filled with the seed crystal and the master alloy is installed on the bottom platform of a LMC directional solidification furnace.

The directional solidification furnace is heated to 1550° C. at a rate of 10° C./min and held for 40-50 min, so as to melt the master alloy in the corundum tube and form a mushy zone with a length of 2-3 mm on the seed crystal. After the holding is completed, the obtained system is subjected to a crystal pulling by pulling down at a rate of 10 μm/s-100 μm/s. After the crystal pulling is completed, the corundum tube is taken out after the directional solidification furnace is cooled to 100° C., to obtain a first Ni—W heterogeneous single crystal test bar with a [001] orientation which deviates from the axial direction by 0-12°.

The first Ni—W heterogeneous single crystal test bar has a diameter of 6.96-11.94 mm, a length of 35 mm, and a gap of 0.02-0.06 mm with the corundum tube.

Step 4: preparing a first single crystal superalloy test bar.

The obtained first Ni—W heterogeneous single crystal test bar is cut to obtain a Ni—W heterogeneous seed crystal that can be put into the shell mould. A single crystal superalloy test bar is prepared by using the obtained Ni—W heterogeneous seed crystal.

The specific process comprises:

The obtained Ni—W heterogeneous seed crystal is put into the corundum tube in the shell mould. The shell mould filled with the Ni—W heterogeneous seed crystal is placed in a directional solidification furnace. A purchased superalloy master alloy block is put into an electromagnetic melting crucible at the upper part of the furnace.

The superalloy is the first generation superalloy developed by Beijing Institute of Aeronautical Materials.

The directional solidification furnace is heated to a temperature of 1550° C. at a rate of 10° C./min, so as to melt the upper surface of the Ni—W heterogeneous seed crystal near the heater of the directional solidification furnace.

The power of the electromagnetic melting crucible is increased to 7.5 kW, so as to completely melt the superalloy master alloy block in the crucible to obtain a superalloy liquid. The superalloy liquid is cast into the shell mould, and the shell mould is full filled with the superalloy liquid.

A mushy zone with a length of 2-3 mm is generated on the upper part of the Ni—W heterogeneous seed crystal by the cast superalloy liquid and held for 10 min-30 min. The mushy zone is a solid-liquid two-phase region generated at the joint of superalloy liquid and Ni—W heterogeneous seed crystal.

After the holding is completed, the obtained system is subjected to a crystal pulling by pulling down at a rate of 40 μm/s-100 μm/s; after the crystal pulling is completed, the product is taken out after the heating furnace is cooled to 300° C., to obtain a first single crystal superalloy test bar with a [001] orientation which deviates from the axial direction by 0-12°.

Step 5: recovering the seed crystal for reuse.

The Ni—W heterogeneous seed crystal is recovered for reuse from the obtained first single crystal superalloy test bar with a [001] orientation which deviates from the axial direction by 0-12°. The specific process comprises:

The shell mould on the obtained first single crystal superalloy test bar with a [001] orientation which deviates from the axial direction by 0-12° is removed. The Ni—W heterogeneous seed crystal in the first single crystal superalloy test bar with a [001] orientation which deviates from the axial direction by 0-12° is cut; the cut Ni—W heterogeneous seed crystal has a length equal to that of the raw Ni—W heterogeneous seed crystal, and it acts as a recovered seed crystal for reuse.

The recovered seed crystal is sanded with a 1200 # sandpaper, so as to obtain a recovered seed crystal with a diameter of 6.94-11.90 mm and a length of 35 mm, wherein the sanded recovered seed crystal has a gap of 0.04-0.15 mm with the inner wall of the corundum tube.

Step 6: preparing other single crystal superalloy test bars.

The obtained recovered seed crystal in step 5 is used to prepare a second single crystal superalloy test bar. The second single crystal superalloy test bar has a [001] orientation which deviates from the axial direction by 0-12°.

The sanded recovered seed crystal is put into the corundum tube of the shell mould. The shell mould is placed into a directional solidification furnace, and the process in step 4 is repeated to obtain a second superalloy test bar.

The process in step 5 is repeated to re-obtain the recovered seed crystal; the process of preparing the second superalloy test bar is repeated to obtain a third superalloy test bar.

The processes of recovering seed crystal and preparing superalloy test bar are repeated until the required number of superalloy test bars are obtained.

The present disclosure will be specifically illustrated by the following four examples. Each example has the same preparation procedure.

The parameters in each example are shown in Table 1:

TABLE 1

| | | Example | | | |
|---|---|---|---|---|---|
| Step | | 1 | 2 | 3 | 4 |
| 1 | The inner diameter of the corundum tube (mm) | 6.98 | 9.04 | 11.98 | 11.96 |
| | The length of the corundum tube (mm) | 40 | 40 | 40 | 40 |
| | The number prepared | 2 | 4 | 8 | 14 |
| | The deviation angle of [001] orientation from the | 0 | 5 | 9 | 12 |
| | axial direction | | | | |
| 2 | The diameter of the seed crystal (mm) | 6.93 | 8.97 | 11.93 | 11.94 |
| | The length of the seed crystal (mm) | 25 | 25 | 25 | 25 |
| 3 | The inner diameter of the corundum tube (mm) | 6.97 | 9.02 | 11.98 | 11.97 |
| | The length of the corundum tube (mm) | 115 | 115 | 115 | 115 |
| | Heating rate (° C./min) | 10 | 10 | 10 | 10 |
| | Heating temperature (° C.) | 1550 | 1550 | 1550 | 1550 |
| | Holding time (min) | 40 | 43 | 50 | 47 |
| | The height of the mushy zone (mm) | 2 | 2.3 | 3 | 2.5 |
| | Pulling rate (μm/s) | 10 | 100 | 70 | 30 |
| | The diameter of the first Ni—W heterogeneous | 6.96 | 8.98 | 11.94 | 11.93 |
| | single crystal test bar (mm) | | | | |
| | The gap between the first Ni—W heterogeneous | 0.02 | 0.06 | 0.04 | 0.03 |
| | single crystal test bar and the corundum tube | | | | |
| | (mm) | | | | |
| | Length | 35 | 35 | 35 | 35 |
| 4 | Heating rate (° C./min) | 10 | 10 | 10 | 10 |
| | Heating temperature (° C.) | 1550 | 1550 | 1550 | 1550 |
| | The power of electromagnetic melting crucible | 7.5 | 7.5 | 7.5 | 7.5 |
| | (kW) | | | | |
| | Holding time (min) | 40 | 43 | 50 | 47 |
| | The height of the mushy zone (mm) | 2 | 2.4 | 3 | 2.6 |
| | Pulling rate (μm/s) | 40 | 100 | 80 | 60 |
| 5 | The diameter of the recovered seed crystal | 6.94 | 8.89 | 11.90 | 11.90 |
| | (mm) | | | | |
| | The length of the recovered seed crystal (mm) | 35 | 35 | 35 | 35 |
| | The gap between the recovered seed crystal and | 0.04 | 0.15 | 0.08 | 0.06 |
| | the corundum tube (mm) | | | | |

What is claimed is:

1. A method for preparing single crystal superalloys by using a Ni—W heterogeneous seed crystal, comprising:
step 1, preparing a shell mould;
step 2, preparing a seed crystal for preparing Ni—W heterogeneous single crystal test bars:
preparing a single crystal test bar by a grain selection method;
step 3, preparing a first Ni—W heterogeneous single crystal test bar with a [001] orientation which deviates from the axial direction by 0-12°:
preparing a Ni—W heterogeneous single test bar with a [001] orientation which deviates from the axial direction by 0-12° by using the seed crystal obtained in step 2;
step 4, preparing a first single crystal superalloy test bar:
cutting the obtained first Ni—W heterogeneous single crystal test bar to obtain a Ni—W heterogeneous seed crystal that can be put into the shell mould;
preparing a single crystal superalloy test bar by using the cut Ni—W heterogeneous seed crystal, specifically comprising:
putting the obtained Ni—W heterogeneous seed crystal into the corundum tube in the shell mould; placing the shell mould filled with the Ni—W heterogeneous seed crystal in a directional solidification furnace; putting a purchased superalloy master alloy block into an electromagnetic melting crucible at the upper part of the furnace; heating the directional solidification furnace to a temperature of 1550° C. at a rate of 10° C./min, so as to melt the upper surface of the Ni—W heterogeneous seed crystal near the heater of the directional solidification furnace;
increasing the power of the electromagnetic melting crucible to 7.5 kW, so as to completely melt the superalloy master alloy block in the crucible to obtain a superalloy liquid; casting the superalloy liquid into the shell mould, and full filling the shell mould with the superalloy liquid;
generating a mushy zone with a length of 2-3 mm on the upper part of the Ni—W heterogeneous seed crystal by the cast superalloy liquid and holding for 10 min-30 min, wherein the mushy zone is a solid-liquid two-phase region generated at the joint of the superalloy liquid and the Ni—W heterogeneous seed crystal;
after the holding is completed, subjecting the obtained system to a crystal pulling by pulling down at a rate of 40 μm/s-100 μm/s; after the crystal pulling is completed, taking out the product after the heating furnace is cooled to 300° C., to obtain a first single crystal superalloy test bar with a [001] orientation which deviates from the axial direction by 0-12°;
step 5, recovering the seed crystal for reuse:
recovering the Ni—W heterogeneous seed crystal for reuse from the obtained first single crystal superalloy test bar with a [001] orientation which deviates from the axial direction by 0-12°, specifically comprising:
removing the shell mould on the obtained first single crystal superalloy test bar with a [001] orientation which deviates from the axial direction by 0-12°;
cutting the Ni—W heterogeneous seed crystal from the first single crystal superalloy test bar with a [001] orientation which deviates from the axial direction by 0-12° after the shell mould is removed, and recovering it for reuse; and
step 6, preparing other single crystal superalloy test bars:
preparing other single crystal superalloy test bars by using the obtained recovered seed crystal, wherein the other single crystal superalloy test bars have a [001] orientation which deviates from the axial direction by 0-12°, and the specific process comprises:
putting the recovered seed crystal into the corundum tube in the shell mould; placing the shell mould in a directional solidification furnace, and repeating step 4 to obtain a second superalloy test bar;
repeating step 5 to re-obtain the recovered seed crystal; repeating the process of preparing the second superalloy test bar to obtain a third superalloy test bar;
repeating the processes of recovering seed crystal and preparing superalloy test bar until the required number of superalloy test bars are obtained.

2. The method as claimed in claim 1, wherein the superalloy master alloy block comprises a DD3 superalloy master alloy block, wherein the DD3 superalloy is the first generation superalloy developed by Beijing Institute of Aeronautical Materials.

3. The method as claimed in claim 1, wherein the shell mould comprises a casting segment and a seed crystal segment with a corundum tube; the seed crystal segment has a length equal to that of the corundum tube, and before preparing a seed crystal, the corundum tube is put into the seed crystal segment; the corundum tube has an inner diameter of 6.98-11.98 mm and a length of 40 mm.

4. The method as claimed in claim 1, wherein the process for preparing a seed crystal for preparing the Ni—W heterogeneous single crystal test bar comprises:
directionally cutting a single crystal cylinder with a [001] orientation which deviates from the axial direction by 0-12° from the single crystal test bar and acting as a seed crystal, wherein the directionally cut seed crystal has a [001] orientation which deviates from the axial direction by 0-12°.

5. The method as claimed in claim 4, wherein the Ni—W heterogeneous seed crystal has a diameter of 6.96-11.94 mm, a length of 35 mm and a gap of 0.02-0.06 mm with the corundum tube.

6. The method as claimed in claim 1, wherein the specific process for preparing a first Ni—W heterogeneous single test bar with a [001] orientation which deviates from the axial direction by 0-12° comprises:
taking another corundum tube as a container for preparing Ni—W heterogeneous single crystal test bars, wherein the corundum tube has an inner diameter of 6.97-11.98 mm and a length of 115 mm;
using a Ni—W alloy as the master alloy, putting the obtained seed crystal and the Ni—W master alloy into the corundum tube in the order of the seed crystal at the bottom and the Ni—W master alloy on the top; installing the corundum tube filled with the seed crystal and the master alloy on the bottom platform of a LMC directional solidification furnace; and
heating the directional solidification furnace to 1550° C. at a rate of 10° C./min and holding for 40-50 min, so as to melt the master alloy in the corundum tube and form a mushy zone with a length of 2-3 mm on the seed crystal; after the holding is completed, subjecting the obtained system to a crystal pulling by pulling down at a rate of 10 μm/s-100 μm/s; after the crystal pulling is completed, taking out the corundum tube after the directional solidification furnace is cooled to 100° C., to obtain the first Ni—W heterogeneous single crystal test bar with a [001] orientation which deviates from the axial direction by 0-12°, wherein
the first Ni—W heterogeneous single crystal test bar has a diameter of 6.96-11.94 mm, a length of 35 mm, and a gap of 0.02-0.06 mm with the corundum tube.

7. The method as claimed in claim 1, wherein the Ni—W heterogeneous seed crystal which is cut from the obtained first single crystal supperalloy test bar with a [001] orientation which deviates from the axial direction by 0-12° has a length equal to that of the raw Ni—W heterogeneous seed crystal and a diameter of 6.94-11.90 mm, so as to ensure the gap between the recovered seed crystal and the inner wall of the corundum tube fall within a range of 0.04-0.15 mm.
